(19) United States
(12) Patent Application Publication
(10) Pub. No.: US 2014/0190635 A1
(43) Pub. Date: Jul. 10, 2014

(54) PLASMA CHAMBER AND APPARATUS FOR TREATING SUBSTRATE

(71) Applicant: PSK INC., Gyeonggi-do (KR)

(72) Inventors: Jong Sik LEE, Seongnam-si (KR); Jeonghee CHO, Hwaseong-si (KR); Hyun Jun KIM, Busan (KR); Chin Wook CHUNG, Seoul (KR); Duksun HAN, Seoul (KR)

(73) Assignees: Industry-University Cooperation Foundation Hanyang University, Seoul (KR); PSK INC., Gyeonggi-do (KR)

(21) Appl. No.: 14/141,740

(22) Filed: Dec. 27, 2013

(30) Foreign Application Priority Data
Jan. 4, 2013 (KR) 10-2013-0001200

(51) Int. Cl. H01J 37/32

(52) U.S. Cl. CPC H01J 37/3211
USPC 156/345.48

(57) ABSTRACT

Provided are a plasma chamber and a substrate treating apparatus. The plasma chamber includes a housing in which a gas is injected to generate plasma, a first coil disposed on one surface of the housing, and a second coil disposed on the other surface of the housing.

### CROSS-REFERENCE TO RELATED APPLICATIONS

This U.S. non-provisional patent application claims priority under 35 U.S.C. §119 of Korean Patent Application No. 10-2013-0001200, filed on Jan. 4, 2013, the entire contents of which are hereby incorporated by reference.

### BACKGROUND OF THE INVENTION

The present invention disclosed herein relates to a plasma chamber and an apparatus for treating a substrate.

A process for manufacturing semiconductors, displays, solar cells, and the like includes a process for treating a substrate by using plasma. For example, in the semiconductor manufacturing process, an etching device used for a dry etching process and an ashing device used for an ashing process may include a chamber for generating plasma. A substrate may be etched or ashed by using the plasma generated in the chamber.

In typical plasma chambers, a coil is wound around a side surface of a chamber, and then, time-varying current flows into the coil to induced electric fields within a chamber, thereby generating plasma. However, in the plasma chambers, the plasma generated in a central portion of the chamber may have a relatively high density, and the plasma generated in an edge portion of the chamber may have a relatively low density.

That is, in the typical plasma chambers, plasma may be nonuniformly generated over an inner space of the chamber. As a result, the substrate may be differently plasma-treated on central and edge portions thereof to deteriorate yield in the substrate treating process.

### SUMMARY OF THE INVENTION

The present invention provides a plasma chamber in which plasma is uniformly generated over an entire region thereof and a substrate treating apparatus.

The present invention also provides a plasma chamber in which a substrate is uniformly treated over an entire area thereof to reduce a failure rate of the substrate to be treated by using plasma and a substrate treating apparatus.

The present invention also provides a plasma chamber having improved process yield and a substrate treating apparatus.

Embodiments of the inventive concept provide plasma chambers including: a housing in which a gas is injected to generate plasma; a first coil disposed on one surface of the housing; and a second coil disposed on the other surface of the housing.

In some embodiments, the housing may have a pillar shape, the first coil may be disposed on a top surface of the housing, and the second coil may be disposed on a side surface of the housing.

In other embodiments, the housing may have a shape in which a plurality of pillars having bottom areas different from each other are connected to each other, the first coil may be disposed on a side surface of a first pillar of the plurality of pillars, and a second coil may be disposed on a side surface of a second pillar of the plurality of pillars.

In still other embodiments, the housing may have a shape in which a plurality of pillars having bottom areas different from each other are connected to each other, the first coil may be disposed on a side surface of a first pillar of the plurality of pillars, and a second coil may be disposed on a top surface of a second pillar of the plurality of pillars.

In even other embodiments, the first pillar may have a bottom area less than that of the second pillar.

In yet other embodiments, the plasma chambers may further include a third coil disposed on a top surface of the first pillar.

In further embodiments, the plasma chambers may further include a fourth coil disposed on a side surface of the second pillar.

In still further embodiments, the housing may have a shape in which a cone pyramid is connected between a plurality of pillars having bottom areas different from each other, the first coil may be disposed on a side surface of one pillar of the plurality of pillars, and the second coil may be disposed on a side surface of the cone pyramid.

In even further embodiments, the plasma chamber may further include a fifth coil disposed on a side surface of the other pillar of the plurality of pillars.

In yet further embodiments, one of the first and second coils may be wound around a core and disposed on a side surface of the housing.

In much further embodiments, the first and second coils may be connected to an RF power source for providing an RF signal.

In still much further embodiments, the first and second coils may be connected to the RF power source in parallel.

In even much further embodiments, the plasma chambers may further include: a first variable capacitor connected to an input terminal of the first coil in series; and a second variable capacitor connected to an input terminal of the second coil in series.

In yet much further embodiments, the plasma chambers may further include: a first capacitive device connected to a ground terminal of the first coil in series; and a second capacitive device connected to a ground terminal of the second coil in series.

In even yet much further embodiments, impedance of the first capacitive device may be set to a half of that of the first coil, and Impedance of the second capacitive device may be set to a half of that of the second coil.

In other embodiments of the inventive concept, substrate treating apparatuses include: a process unit providing a space in which a substrate is disposed to plasma-treat the substrate; and a plasma generation unit generating plasma from a gas to supply the generated plasma into the process unit, wherein the plasma generation unit includes: an RF power source for providing an RF signal a housing in which a gas is injected to generate plasma; a first coil disposed on one surface of the housing, the first coil receiving the RF signal to induce electromagnetic fields in the housing; and a second coil disposed on the other surface of the housing, the second coil receiving the RF signal to induce electromagnetic fields in the housing.

In some embodiments, the housing may have a pillar shape, the first coil may be disposed on a top surface of the housing, and the second coil may be disposed on a side surface of the housing.

In other embodiments, the housing may have a shape in which a plurality of pillars having bottom areas different from each other are connected to each other, the first coil may be disposed on a side surface of a first pillar of the plurality of pillars, and a second coil may be disposed on a side surface of a second pillar of the plurality of pillars.

In still other embodiments, the housing may have a shape in which a plurality of pillars having bottom areas different from each other are connected to each other, the first coil may be disposed on a side surface of a first pillar of the plurality of pillars, and a second coil may be disposed on a top surface of a second pillar of the plurality of pillars.

In even other embodiments, the first pillar may have a bottom area less than that of the second pillar.

In yet other embodiments, the plasma generation unit may further include a third coil disposed on a top surface of the first pillar.

In further embodiments, the plasma generation unit may further include a fourth coil disposed on a side surface of the second pillar.

In still further embodiments, the housing may have a shape in which a cone pyramid is connected between a plurality of pillars having bottom areas different from each other, and the second coil may be disposed on a side surface of the cone pyramid.

In even further embodiments, the plasma generation unit may further include a fifth coil disposed on a side surface of the other pillar of the plurality of pillars.

In yet further embodiments, one of the first and second coils may be wound around a core and disposed on a side surface of the housing.

### BRIEF DESCRIPTION OF THE DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view of a substrate treating apparatus using a plasma generation unit according to an embodiment of the present invention;

FIGS. 2 to 11 are perspective views of a plasma chamber according to various embodiments of the present invention;

FIG. 12 is a view of a core disposed on a side surface of a housing according to an embodiment of the present invention;

FIG. 13 is a view of the core around which a lead wire is wound according to an embodiment of the present invention;

FIG. 14 is a circuit diagram of a plasma generation unit according to an embodiment of the present invention; and

FIG. 15 is a circuit diagram of a plasma generation unit according to another embodiment of the present invention.

### DETAILED DESCRIPTION OF PREFERRED EMBODIMENTS

Advantages and features of the present invention, and implementation methods thereof will be clarified through following embodiments described with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Further, the present invention is only defined by scopes of claims.

If not defined otherwise, all of the terms used (including technical or scientific terms) are equivalent to the counterparts as understood generally by one in the killed in the art. Usual terms as defined in the dictionary are to be interpreted correspondingly to the context of the related technology rather than ideally or excessively formally unless the present invention clearly defines the same.

In the following description, the technical terms are used only for explaining a specific exemplary embodiment while not limiting the prevent invention. The terms of a singular form may include plural forms unless specifically mentioned. The meaning of ‘comprises’ and/or ‘comprising’ specifies a composite, component, element, process, operation and/or device but does not exclude other composites, components, elements, processes, operations and/or devices. In the specification, ‘and/or’ means that it includes at least one of listed components.

Hereinafter, specific embodiments will be described in detail with reference to the accompanying drawings.

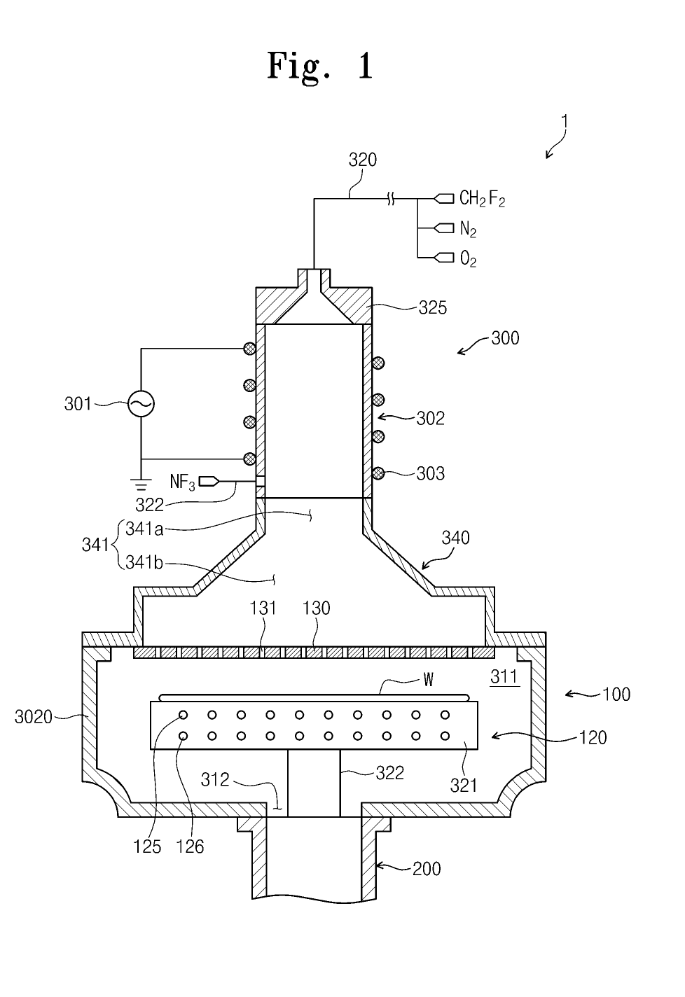

FIG. 1 is a view of a substrate treating apparatus using a plasma generation unit according to an embodiment of the present invention.

Referring to FIG. 1, a substrate treating apparatus 1 may perform an etching or ashing process on a thin film disposed on a substrate W by using plasma. The thin film to be etched or ashed may be a nitride. For example, the nitride may be a silicon nitride.

The substrate treating apparatus 1 may include a process unit 100, an exhaust unit 200, and a plasma generation unit 300. The process unit 100 may provide a space in which the etching or ashing process is performed on the substrate placed therein. The exhaust unit 200 may exhaust a process gas staying in the process unit 100 and byproducts generated while the substrate W is treated to the outside to maintain the inside of the process unit 100 at a preset pressure. The plasma generation unit 300 may generate plasma from a process gas supplied from the outside to supply the generated plasma into the process unit 100.

The process unit 100 may include a process chamber 110, a substrate support unit 120, and a baffle 130. A treating space 111 in which the substrate treating process is performed may be defined in the process chamber 110. The process chamber 110 may have an opened upper wall and a sidewall in which an opening (not shown) is defined. The substrate may be loaded into or unloaded from the process chamber 110 through the opening. The opening may be switched by a switching member such as a door (not shown). An exhaust hole 112 may be defined in a bottom surface of the process chamber 110. The exhaust hole 112 may be connected to the exhaust unit 200 to provide a passage through which the gas staying in the process chamber 110 and the byproducts are discharged to the outside.

The substrate support unit 120 may support the substrate W. The substrate support unit 120 may include a susceptor 121 and a support shaft 122. The susceptor 121 may be disposed within the treating space 111 and have a circular plate shape. The susceptor 121 may be supported by the support shaft 122. The substrate W may be placed on a top surface of the susceptor 121. An electrode (not shown) may be provided in the susceptor 121. The electrode may be connected to an external power source to generate static electricity by the applied power. The generated static electricity may fix the substrate W to the susceptor 121. A heating member 125 may be provided in the susceptor 121. For example, the heating member 125 may include a heating coil. A cooling member 126 may be provided in the susceptor 121. The cooling member may be provided as a cooling line through which coolant flows. The heating member 125 may heat the substrate W at a preset temperature. The cooling member 126 may forcibly cool the substrate W. The substrate W to be treated may be cooled at room temperature or a temperature required for a next process.

The baffle 130 may be disposed above the susceptor 121. Holes 131 may be defined in the baffle 130. The holes 131 may be provided as through-holes extending from a top surface to a bottom surface of the baffle 130. The holes 131 may be uniformly distributed in an entire region of the baffle 130.

Referring again FIG. 1, the plasma generation unit 300 may be disposed in an upper portion of the process chamber 110. The plasma generation unit 300 may discharge a source gas to generate plasma, thereby supplying the generated plasma into the treating space 111. The plasma generation unit 300 may include a power source 301, a housing 302, and a coil 303. Furthermore, the plasma generation unit 300 may further include a first source gas supply part 320, a second source gas supply part 322, and an inlet duct 340.

The housing 302 may be disposed outside the process chamber 110. For example, the housing 302 may be disposed above the process chamber 110 and then coupled to the process chamber 110. A discharge space having opened top and bottom surfaces may be defined in the housing 302.

An upper end of the housing 302 may be sealed by a gas supply port 325. The gas supply port 325 may be connected to the first source gas supply part 320. The first source gas may be supplied into the discharge space through the gas supply port 325. The first source gas may include difluoromethane (CH₂F₂), nitrogen (N₂), and oxygen (O₂). Selectively, the first source gas may further include different kinds of gases such as tetrafluoromethane (CF₄).

The coil 303 may be an inductively coupled plasma (ICP) coil. The coil 303 may be wound around the housing 302 several times. The coil 303 may be wound around the housing 302 in a region corresponding to the discharge space. The coil 303 may have one end connected to the power source 301 and the other end that is grounded.

The power source 301 may supply high frequency current into the coil 303. The high frequency current supplied into the coil 303 may be applied to the discharge space. Induced electric fields may be formed in the discharge space by the high frequency current. The first source gas within the discharge space may receive energy required for ionization from the induced electric fields and thus be changed into a plasma state.

The inlet duct 340 may be disposed between the housing 302 and the process chamber 110. The inlet duct 340 may seal the opened top surface of the process chamber 110, and a lower end of the inlet duct 340 may be coupled to the baffle 130. An inflow space 341 may be defined in the inlet duct 340. The inflow space 341 may connect the discharge space to the treating space 111 to provide a passage through which the plasma generated in the discharge space is supplied into the treating space 111.

The inflow space 341 may include an inflow hole 341a and a diffusion space 341b. The inflow hole 341a may be defined under the discharge space and connected to the discharge space. The plasma generated in the discharge space may be introduced through the inflow hole 341a. The diffusion space 341b may be defined under the inflow hole 341a to connect the inflow hole 341a to the treating space 111. The diffusion space 341a may have a cross-sectional area that gradually increases downward. The diffusion space 341b may have an inverted hopper shape. The plasma supplied through the inflow hole 341a may be diffused while passing through the diffusion space 341b.

The second source gas supply part 322 may be connected to a passage through which the plasma generated in the discharge space is supplied into the process chamber 110. For example, the second source gas supply unit 322 may supply a second source gas into a passage through which the plasma flows between a position at which a lower end of the coil is provided and a position at which an upper end of the diffusion space 341b is provided. For example, the second source gas may include nitrogen trifluoride (NF₃).

Selectively, the etching or ashing process may be performed by using only the first source gas without supplying the second source gas.

A structure of the plasma generation unit 300 is not limited to the foregoing example. As described below, the plasma generation unit 300 may have various structures to generate plasma from the source gas.

The plasma generation unit according to an embodiment of the present invention may include an RF power source for providing an RF signal and a plasma chamber for generating plasma by using the RF signal. The plasma chamber may include a housing and a coil.

According to an embodiment, in the plasma chamber, a plurality of coils are disposed on a housing. Here, the plurality of coils may be disposed on different surfaces of the housing, respectively.

A gas may be injected into the housing to generate plasma. According to an embodiment, the housing may receive high frequency power from the RF power source to change the gas injected into a container into a plasma state by using the high frequency power.

A plurality of coil may be disposed on the housing. According to an embodiment, the plasma chamber may include a first coil disposed on one surface of the housing and a second coil disposed on the other surface of the housing.

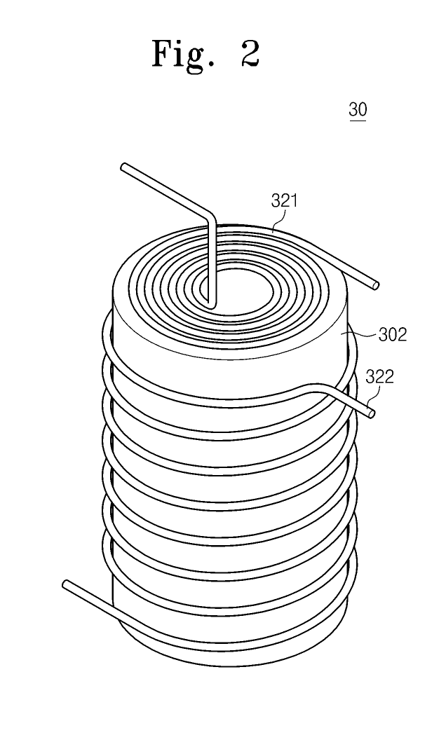

FIG. 2 is a perspective view of a plasma chamber 30 according to an embodiment of the present invention.

The plasma chamber 30 according to an embodiment may include a pillar-shaped housing 302. For example, as shown in FIG. 2, the housing 302 may have a cylindrical shape.

The plasma chamber 30 may include a first coil 321 disposed on a top surface of the housing 302 and a second coil disposed on a side surface of the housing 302. That is, the first and second coils 321 and 322 may be disposed on different surfaces of the housing 302, respectively.

Although the housing 302 of the plasma chamber 30 has the cylindrical shape in FIG. 2, the present invention is not limited to a shape of the housing 302. For example, the housing 302 may have various shapes according to embodiments.

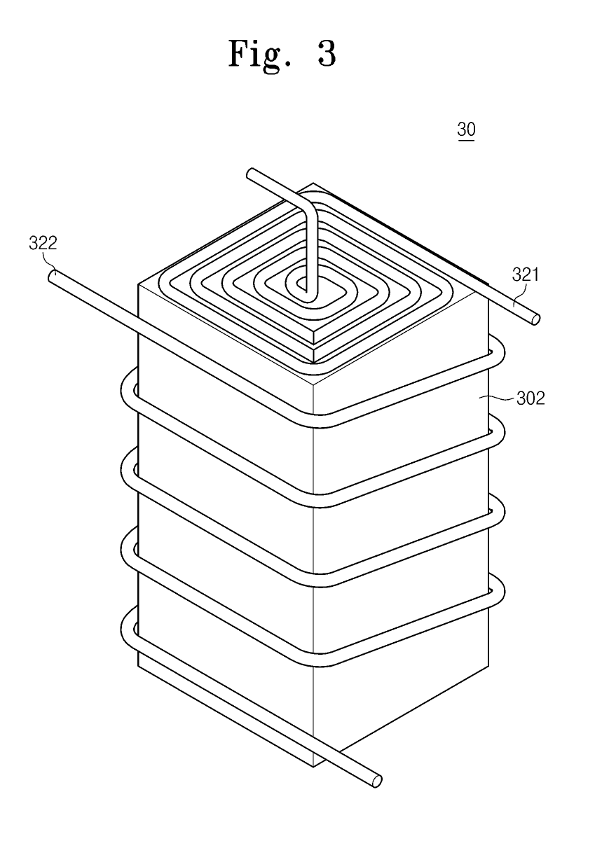

FIG. 3 is a perspective view of a plasma chamber 30 according to another embodiment of the present invention. Referring to FIG. 3, a housing 302 of the plasma chamber 30 may have a prism shape. The prism may include various prisms such as a triangular prism, a square prism, a pentagonal prism, a hexagonal prism, and the like.

Although the housing 302 of FIGS. 2 and 3 has a single pillar shape, the housing 302 may have a shape in which a plurality of different pillars are connected to each other according to embodiments.

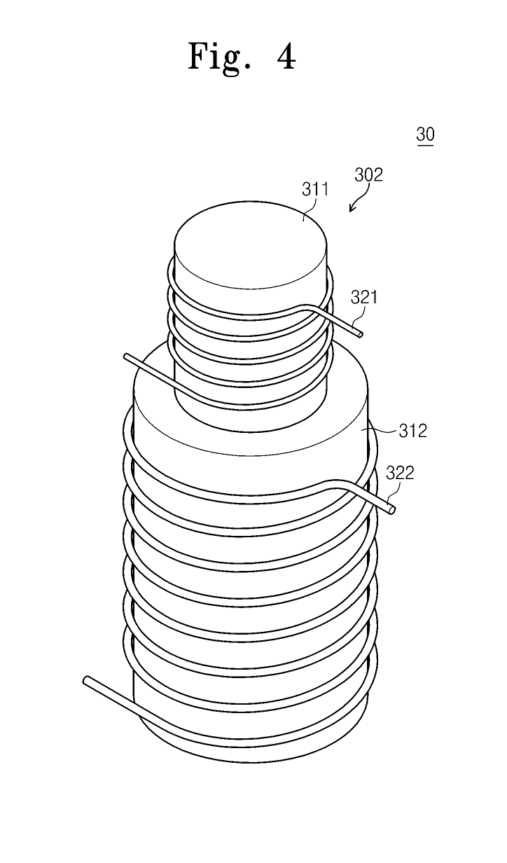

FIG. 4 is a perspective view of a plasma chamber 30 according to another embodiment of the present invention.

Referring to FIG. 4, the housing 302 may have a shape in which a plurality of different pillars having bottom areas different from each other are connected to each other. For example, as shown in FIG. 4, when the housing 302 includes two cylinders 311 and 312 connected to each other, the cylinders 311 and 312 may have radii different from each other. When the housing 302 includes two prisms connected to each other, the prisms may have bottom areas different from each other.

According to an embodiment of the present invention, the first coil 321 may be disposed on a side surface of a first pillar 311 of a plurality of pillars. Also, the second coil 322 may be disposed on a side surface of a second pillar 302 of the plurality of pillars. As described above, the plurality of coils included in the plasma chamber may be disposed on different surfaces of the housing, respectively.

Although the plasma chamber 30 of FIG. 4 includes a housing 302 having a shape in which two different cylinders 311 and 312 having diameters different from each other are connected to each other, the housing 302 may have a shape in which a cylinder and prism are connected to each other, or prisms of which the number of vertexes on bottom surfaces is different from each other are connected to each other according to embodiments.

According to embodiments, the housing 302 may have a shape in which three or more pillars are connected to each other.

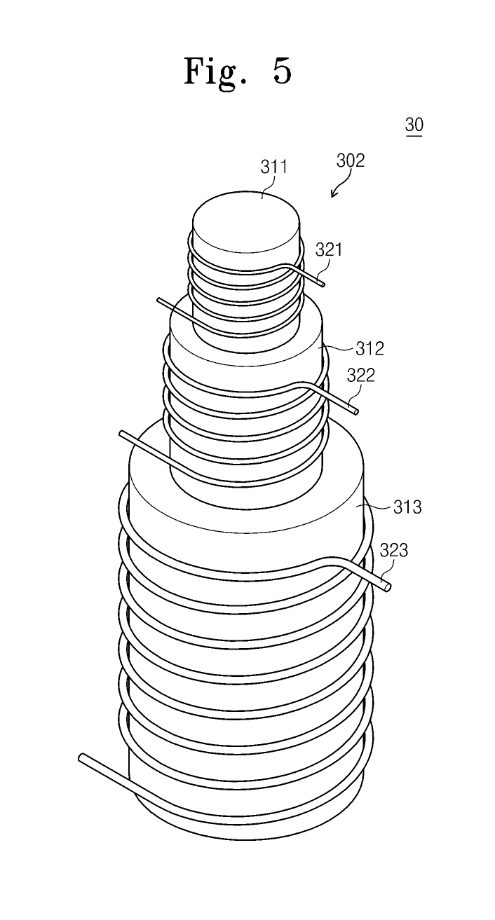

FIG. 5 is a perspective view of a plasma chamber 30 according to another embodiment of the present invention.

Referring to FIG. 5, the housing 302 may have a shape in which three pillars 311, 312, 313 are connected to each other. Here, the three pillars may have bottom areas different from each other. Coils 321, 322, and 323 may be disposed on side surfaces of the three pillars 311, 312, 313, respectively.

According to an embodiment of the present invention, one of the plurality of coils may be disposed on a side surface of a first pillar, and the other one of the plurality of coils may be disposed on a top surface of a second pillar.

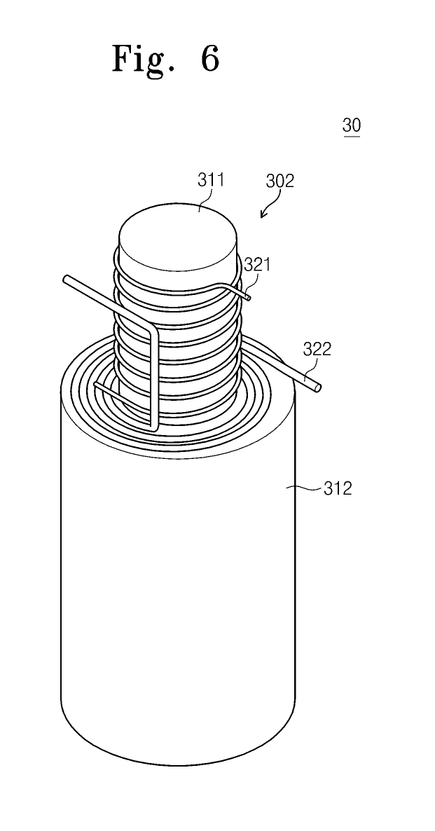

FIG. 6 is a perspective view of a plasma chamber 30 according to another embodiment of the present invention.

Referring to FIG. 6, the housing 302 may have a shape in which a plurality of pillars 311 and 312 having bottom areas different from each other are connected to each other. Also, the first coil 321 may be disposed on a side surface of the first pillar 311 of the plurality of pillars 311 and 312, and a second coil 322 may be disposed on a top surface of the second pillar 302 of the plurality of pillars 311 and 312.

According to an embodiment, the first pillar 311 may have a bottom area less than that of the second pillar 302. That is, when the housing 302 has a shape in which pillars having different bottom areas and are connected to each other, one of the plurality of coils may be disposed on a side surface of the pillar having the relatively small bottom area, and the other coil of the plurality of coils may be disposed on a top surface of the pillar having the relatively large bottom area.

According to an embodiment of the present invention, the plasma chamber may further include a third coil disposed on a top surface of the pillar having the relatively small bottom area.

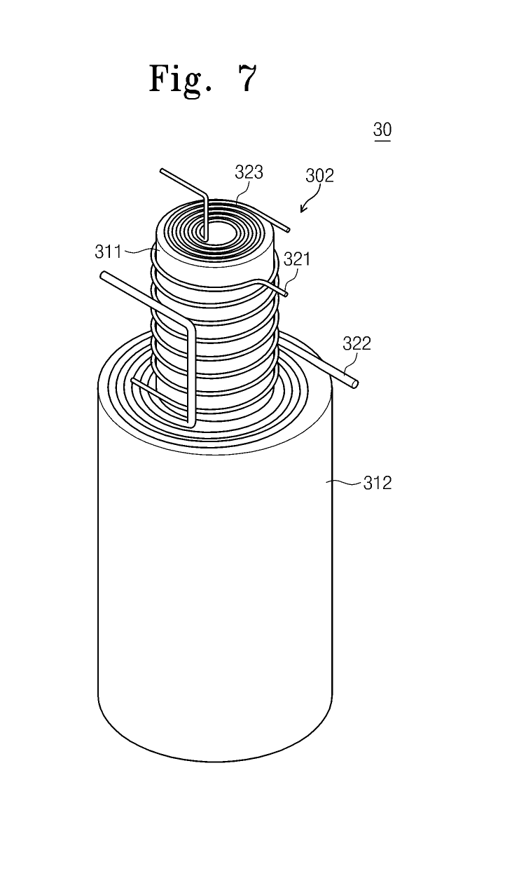

FIG. 7 is a perspective view of a plasma chamber 30 according to another embodiment of the present invention. Referring to FIG. 7, a third coil 323 may be additionally disposed on a top surface of the first pillar 311. The plasma chamber 30 may include three coils disposed on surfaces different from each other.

According to another embodiment of the preset invention, the plasma chamber may further include a fourth coil disposed on a side surface of the pillar having a relatively large bottom area.

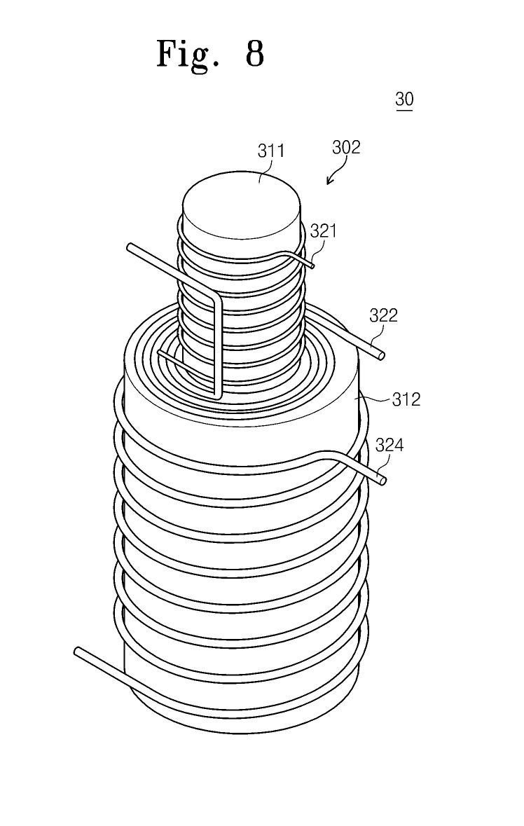

FIG. 8 is a perspective view of a plasma chamber 30 according to another embodiment of the present invention. Referring to FIG. 8, a fourth coil 324 may be disposed on a side surface of a second pillar 302 in addition to the first and second coils 321 and 322.

According to embodiments, the plasma chamber may include the third and fourth coils 323 and 324 together with each other.

According to an embodiment of the present invention, the housing 302 may have a shape in which a cone pyramid is connected between a plurality of pillars.

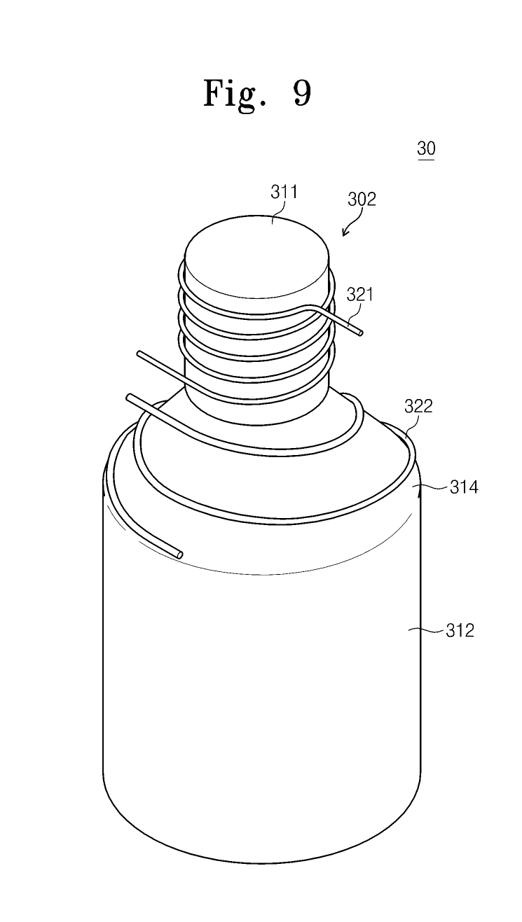

FIG. 9 is a perspective view of a plasma chamber 30 according to an embodiment of the present invention. Referring to FIG. 9, the housing 302 may have a shape in which a cone pyramid 314 is connected between a plurality of pillars 311 and 312 having bottom areas different from each other.

The cone pyramid 314 may have a top surface congruent with a bottom surface of the first pillar 311 and a bottom surface congruent with a bottom surface of the second pillar 302. The cone pyramid 314 may have various shapes such as a truncated cone, a triangular pyramid, a quadrangular pyramid, and the like.

As shown in FIG. 9, the first coil 321 may be disposed on a side surface of one pillar 311 of the plurality of pillars 311 and 312. Also, the second coil 322 may be disposed on a side surface of the cone pyramid 314.

According to another embodiment of the preset invention, the plasma chamber may further include a fifth coil disposed on a side surface of the other pillar of the plurality of pillars 311 and 312.

FIG. 10 is a perspective view of a plasma chamber 30 according to another embodiment of the present invention. Referring to FIG. 10, the plasma chamber 30 may further include a fifth coil 325 disposed on a side surface of a second pillar 302 in addition to a first coil 321 disposed on a side surface of a first pillar 311 and a second coil 322 disposed on a side surface of a cone pyramid 314.

According to embodiments, the plasma chamber may further include a sixth coil on a top surface of the first pillar 311 instead of the fifth coil 325. Alternatively, the plasma chamber may include the sixth coil together with the fifth coil 325.

According to an embodiment of the present invention, one of the first and second coils may be wound around a core and then disposed on a side surface of the housing.

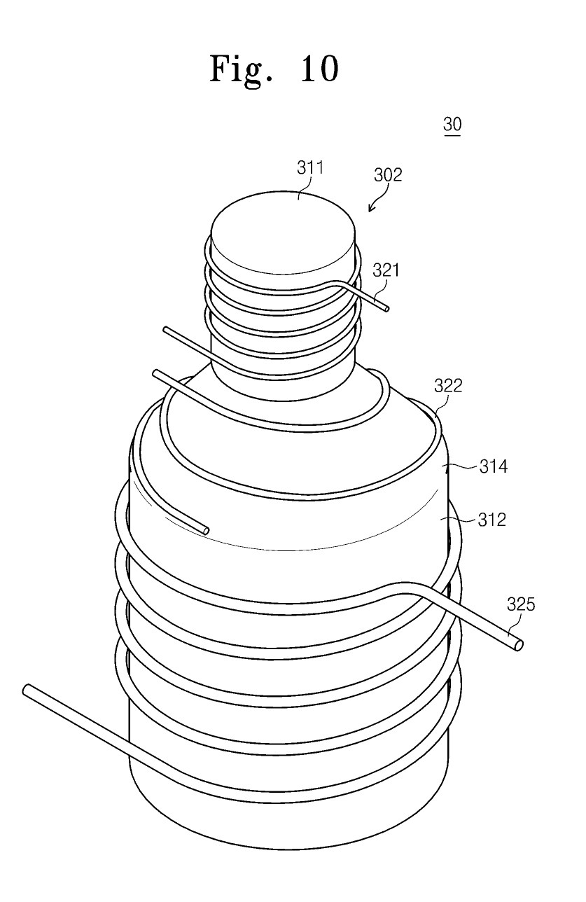

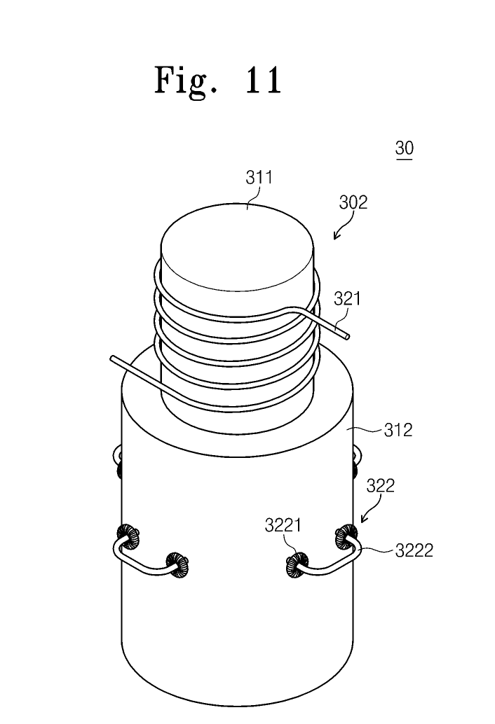

FIG. 11 is a perspective view of a plasma chamber 30 according to another embodiment of the present invention. Referring to FIG. 11, a first coil 321 of the plasma chamber 30 may be wound and disposed around a side surface of a first pillar 311, and a second coil 322 may be wound around a core 3221 and disposed on a side surface of a second pillar 302.

According to an embodiment, the core 3221 may be disposed around a housing.

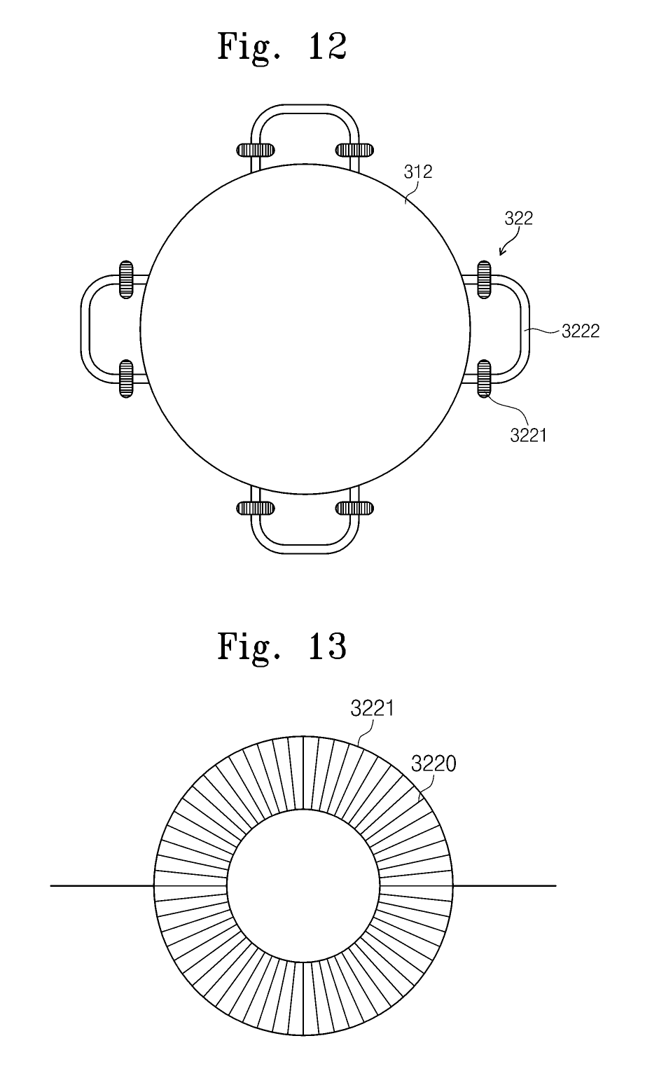

FIG. 12 is a plan view of cores 3221 disposed on a side surface of a housing 302 according to an embodiment of the present invention. Referring to FIG. 12, the cores 3221 may be disposed around a side surface of a container at the same distance. According to an embodiment, the number of cores and a distance between the cores may vary.

Each of the cores 3221 may be formed of a ferromagnetic material such as ferrite. The core 3221 may be fixed to the side surface of the container by an insulation body 3222 such as quartz.

A lead wire may be wound around the core 3221.

FIG. 13 is a view of the core 3221 around which a lead wire 3220 is wound according to an embodiment of the present invention. Referring to FIG. 13, the lead wire 3220 may be wound along an outer surface of the core 3221 of which a center is punched. The lead wires wound around the plurality of cores 3221 fixed along a circumference of a side surface of the housing may be connected to each other in series.

According to embodiments, as shown in FIG. 11, in the plasma chamber 30, a first coil 321 wound around a core may be disposed on a side surface of a first pillar 311, and a second coil 322 may be wound around a side surface of a second pillar 302.

FIG. 14 is a circuit diagram of a plasma generation unit 300 according to an embodiment of the present invention.

Referring to FIG. 14, the plasma generation unit 300 may include an RF power source 301 and a plasma chamber 30.

The RF power source 301 may provide an RF signal. According to an embodiment, the RF power source 301 may generate the RF signal to transmit the RF signal to the plasma chamber 30, thereby transmitting high frequency power into the chamber 30.

According to an embodiment of the present invention, the RF power source 301 may generate a RF signal having a sinusoidal wave to output the RF signal. However, the present invention is not limited thereto. For example, the RF power source 301 may generate various waves such as a square wave, a triangle wave, a triangle wave, a pulse wave, and the like.

The plasma chamber 30 may generate plasma by using the RF signal. The plasma chamber 30 may include a housing 302, a first coil 321, and a second coil 322.

A gas may be injected into the housing 302 to generate plasma.

According to an embodiment, the housing 302 may change a gas injected into a container into a plasma state by using high frequency power transmitted through the RF signal.

The first coil 321 may be disposed on one surface of the housing 302 to receive the RF signal from the RF power source 301, thereby inducing electromagnetic fields in the housing 302. The second coil 322 may be disposed on the other surface of the housing 302 to receive the RF signal, thereby inducing electromagnetic fields in the housing 302.

In the plasma chamber 30 of FIG. 14, the housing 302 may have a shape in which a cone pyramid is connected between two pillars having bottom areas different from each other. Here, the first coil 321 may be disposed on a side surface of one pillar of the two pillars, and the second coil 322 is disposed on a side surface of the cone pyramid. However, the plasma chamber 30 is not limited to the embodiment of FIG. 14, and the plasma chamber 30 may be used according to the foregoing embodiment of the present invention.

According to an embodiment of the present invention, the first and second coils 321 and 322 may be connected to one RF power source 301 in parallel. However, the number of RF power source 301 is not limited, and a plurality of RF power sources 301 corresponding to the number of coil provided in the plasma chamber 30.

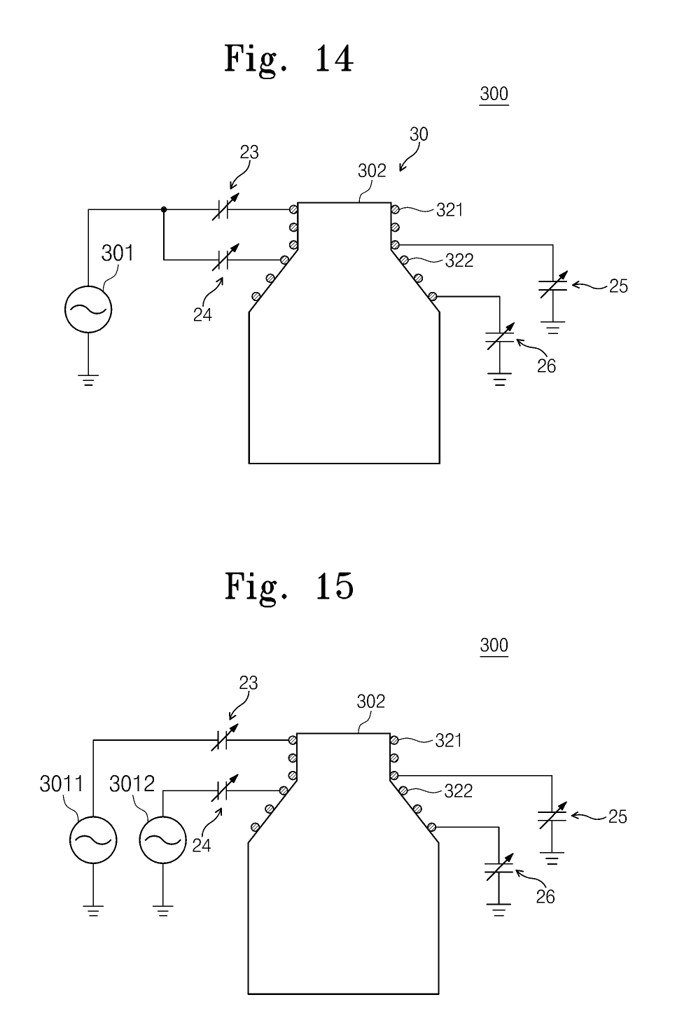

FIG. 15 is a circuit diagram of a plasma generation unit 300 according to another embodiment of the present invention. Referring to FIG. 15, the plasma generation unit 300 may include RF power sources 3011 and 3012 corresponding to the number of coil 321 and 322. For example, the first RF power source 301 may be connected to the first coil 321 to provide an RF signal. The second RF power source 3012 may be connected to the second coil 322 to provide an RF signal.

Referring to FIGS. 14 and 15, according to an embodiment of the present invention, the plasma generation unit may further include a first variable capacitor 23 connected to an input terminal of the first coil 321 in series and a second variable capacitor 24 connected to an input terminal of the second coil 322 in series. The first variable capacitor 23 and the second variable capacitor 24 may be adjusted in capacitance by a controller (not shown) to control an amount of RF power transmitted into the first and second coils 321 and 322 from the RF power source.

As shown in FIGS. 14 and 15, according to an embodiment of the present invention, the plasma generation unit may further include a first capacitive device 25 connected to a ground terminal of the first coil 321 in series and a second capacitive device 26 connected to a ground terminal of the second coil 322 in series.

Impedance of the first capacitive device 25 may be set to a half of that of the first coil 321, and impedance of the second capacitive device 26 may be set to a half of that of the second coil 322.

Unlike the first and second variable capacitors 23 and 24 for adjusting the amount of RF power transmitted into the first and second coils 321 and 322, the first and second capacitive devices 25 and 26 may be used to reduce a potential difference between both ends of the first coil 321 and a potential difference between both ends of the second coil 322, thereby applying equilibrium potential to the coils 321 and 322.

As described above, the plasma chamber in which the plurality of coils are respectively disposed on different surfaces of the housing and the substrate treating apparatus were described. According to the plasma chamber and the substrate treating apparatus, high-density plasma may be uniformly generated over the entire region within the container regardless of a distance from the central shaft of the housing. Also, the plasma chamber and the plasma generation apparatus may uniformly treat the entire area of the substrate to be treated by using plasma to reduce the failure rate of the substrate and improve process yield.

According to the embodiments of the present invention, the high-density plasma may be uniformly generated regardless of a distance from the central shaft of the chamber.

According to the embodiments of the present invention, the plasma-treated substrate may be reduced in failure rate to improve the process yield.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A plasma chamber comprising:
a housing in which a gas is injected to generate plasma;
a first coil disposed on one surface of the housing; and
a second coil disposed on the other surface of the housing.

2. The plasma chamber of claim 1, wherein the housing has a pillar shape,
the first coil is disposed on a top surface of the housing, and
the second coil is disposed on a side surface of the housing.

3. The plasma chamber of claim 1, wherein the housing has a shape in which a plurality of pillars having bottom areas different from each other are connected to each other,
the first coil is disposed on a side surface of a first pillar of the plurality of pillars, and
a second coil is disposed on a side surface of a second pillar of the plurality of pillars.

4. The plasma chamber of claim 1, wherein the housing has a shape in which a plurality of pillars having bottom areas different from each other are connected to each other,
the first coil is disposed on a side surface of a first pillar of the plurality of pillars, and
a second coil is disposed on a top surface of a second pillar of the plurality of pillars.

5. The plasma chamber of claim 4, wherein the first pillar has a bottom area less than that of the second pillar.

6. The plasma chamber of claim 4, further comprising a third coil disposed on a top surface of the first pillar.

7. The plasma chamber of claim 4, further comprising a fourth coil disposed on a side surface of the second pillar.

8. The plasma chamber of claim 1, wherein the housing has a shape in which a cone pyramid is connected between a plurality of pillars having bottom areas different from each other,
the first coil is disposed on a side surface of one pillar of the plurality of pillars, and
the second coil is disposed on a side surface of the cone pyramid.

9. The plasma chamber of claim 8, further comprising a fifth coil disposed on a side surface of the other pillar of the plurality of pillars.

10. The plasma chamber of claim 1, wherein one of the first and second coils is wound around a core and disposed on a side surface of the housing.

11. The plasma chamber of claim 1, wherein the first and second coils are connected to an RF power source for providing an RF signal.

12. The plasma chamber of claim 11, wherein the first and second coils are connected to the RF power source in parallel.

13. The plasma chamber of claim 11, further comprising:
a first variable capacitor connected to an input terminal of the first coil in series; and
a second variable capacitor connected to an input terminal of the second coil in series.

14. The plasma chamber of claim 11, further comprising:
a first capacitive device connected to a ground terminal of the first coil in series; and
a second capacitive device connected to a ground terminal of the second coil in series.

15. The plasma chamber of claim 14, wherein impedance of the first capacitive device is set to a half of that of the first coil, and
Impedance of the second capacitive device is set to a half of that of the second coil.

16. A substrate treating apparatus comprising:
a process unit providing a space in which a substrate is disposed to plasma-treat the substrate; and
a plasma generation unit generating plasma from a gas to supply the generated plasma into the process unit,
wherein the plasma generation unit comprises:
an RF power source for providing an RF signal
a housing in which a gas is injected to generate plasma;
a first coil disposed on one surface of the housing, the first coil receiving the RF signal to induce electromagnetic fields in the housing; and
a second coil disposed on the other surface of the housing, the second coil receiving the RF signal to induce electromagnetic fields in the housing.

17. The substrate treating apparatus of claim 16, wherein the housing has a pillar shape,
the first coil is disposed on a top surface of the housing, and
the second coil is disposed on a side surface of the housing.

18. The substrate treating apparatus of claim 16, wherein the housing has a shape in which a plurality of pillars having bottom areas different from each other are connected to each other,
the first coil is disposed on a side surface of a first pillar of the plurality of pillars, and
a second coil is disposed on a side surface of a second pillar of the plurality of pillars.

19. The substrate treating apparatus of claim 16, wherein the housing has a shape in which a plurality of pillars having bottom areas different from each other are connected to each other,
the first coil is disposed on a side surface of a first pillar of the plurality of pillars, and
a second coil is disposed on a top surface of a second pillar of the plurality of pillars.

20. The substrate treating apparatus of claim 19, wherein the first pillar has a bottom area less than that of the second pillar.

21. The substrate treating apparatus of claim 19, wherein the plasma generation unit further comprises a third coil disposed on a top surface of the first pillar.

22. The substrate treating apparatus of claim 19, wherein the plasma generation unit further comprises a fourth coil disposed on a side surface of the second pillar.

23. The substrate treating apparatus of claim 16, wherein the housing has a shape in which a cone pyramid is connected between a plurality of pillars having bottom areas different from each other, and
the second coil is disposed on a side surface of the cone pyramid.

24. The substrate treating apparatus of claim 23, wherein the plasma generation unit further comprises a fifth coil disposed on a side surface of the other pillar of the plurality of pillars.

25. The substrate treating apparatus of claim 16, wherein one of the first and second coils is wound around a core and disposed on a side surface of the housing.
